(19) United States
(12) Patent Application Publication
(10) Pub. No.: US 2015/0048504 A1
(43) Pub. Date: Feb. 19, 2015

(54) PACKAGE ASSEMBLY FOR CHIP AND METHOD OF MANUFACTURING SAME

(71) Applicant: Ambit Microsystems (Zhongshan) LTD., Zhongshan (CN)

(72) Inventor: YUE-RONG WANG, Zhongshan (CN)

(73) Assignee: AMBIT MICROSYSTEMS (ZHONGSHAN) LTD., Zhongshan (CN)

(21) Appl. No.: 14/059,455

(22) Filed: Oct. 22, 2013

(30) Foreign Application Priority Data
Aug. 19, 2013 (CN) 2013103625503

(51) Int. Cl. H01L 23/00; H01L 21/56; H01L 23/28; H01L 23/12

(52) U.S. Cl. CPC H01L 24/17; H01L 24/81; H01L 23/12; H01L 21/56; H01L 23/28
USPC 257/738; 438/126

(57) ABSTRACT

A package assembly includes a substrate, a chip located on the substrate, solder balls, pads, an encapsulation and separating posts corresponding to the pads one by one. The chip is electrically connected to the pads via the solder balls, and is encapsulated by the encapsulation. The separating posts extend from the edge of the corresponding pads in a direction away from the pads. The solder balls are accommodated in the separating posts to avoid a short connection between any two adjacent solder balls. A method of manufacturing the package assembly is also provided.

### BACKGROUND

1. Technical Field

The present disclosure generally relates to package assemblies for chips and methods of manufacturing the package assemblies; and more particularly to a package assembly typically incorporating a flip chip, and a method of manufacturing such package assembly.

2. Description of Related Art

Most package assemblies for flip chips employ a solder mask dam on a substrate, to avoid tin bridging. Typically, a large amount of solder mask dam is placed on the substrate, and therefore a distance between centers of adjacent pads has to be more than 100 μm (micrometers) to provide enough space for placing the solder mask dam between the adjacent pads. Thus the substrate is relatively large, and the package assembly is correspondingly bulky. In addition, a pre-soldering operation is needed. Accordingly, the package assembly not only militates against the trend toward miniaturization of package assemblies, but also is costly to manufacture.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a cross-sectional view of a package assembly for a chip, according to a first exemplary embodiment of the disclosure.

FIG. 2 is a flow chart of an exemplary method of manufacturing the package assembly of FIG. 1.

FIG. 3 is a cross-sectional view of forming pads and an electroplating line on a substrate, according to the method of FIG. 2.

FIG. 4 is similar to FIG. 3, but showing a dry film covering the exposed substrate and surfaces of the pads and the electroplating line.

FIG. 5 is similar to FIG. 4, but showing portions of the dry film removed and separating posts electroplated on the substrate.

FIG. 6 is similar to FIG. 5, but showing all the remaining portions of the dry film removed, a protective film electroplated on the separating posts and the pads, and the electroplating line removed.

FIG. 7 is similar to FIG. 6, but showing a chip having solder balls set on the substrate, with the solder balls accommodated in the separating posts.

FIG. 8 is similar to FIG. 7, but showing an encapsulation formed on the substrate.

FIG. 9 is a cross-sectional view of a package assembly for a chip, according to a second exemplary embodiment of the disclosure.

### DETAILED DESCRIPTION

The disclosure is illustrated by way of example and not by way of limitation in the figures of the accompanying drawings in which like reference numerals indicate similar elements. It should be noted that references to “an” or “one” embodiment in this disclosure are not necessarily to the same embodiment, and such references can mean “at least one.”

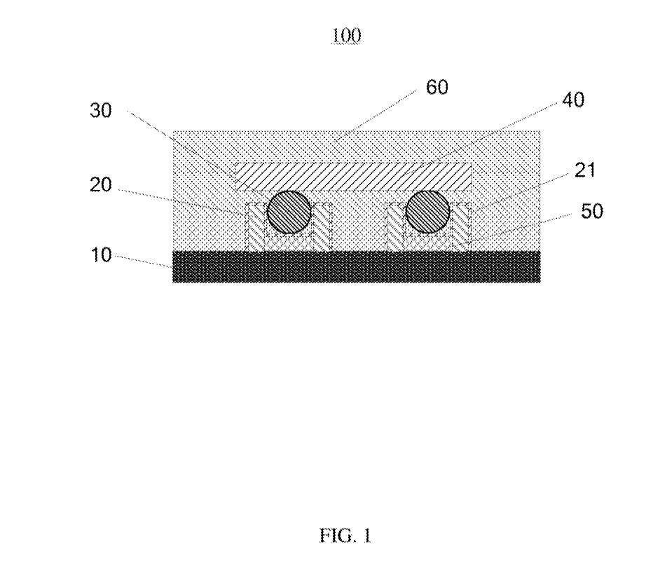

FIG. 1 shows a package assembly 100 for a chip, according to a first exemplary embodiment of the disclosure. The package assembly 100 includes a substrate 10, a plurality of pads 50 located on the substrate 10, a plurality of solder balls 30, a chip 40, and an encapsulation 60. The chip 40 is electrically connected to the plurality of pads 50 via the plurality of solder balls 30, and is encapsulated by the encapsulation 60. The chip 40 can for example be a flip chip. The package assembly 100 also includes a plurality of separating posts 20, which correspond to the plurality of pads 50 one-to-one. Each separating post 20 is hollow and extends from the substrate 10 at a circumferential edge of the corresponding pad 50 in an upward direction away from the substrate 10. In the illustrated embodiment, an inner wall of each separating post 20 surrounds and adjoins the corresponding pad 50. In particular, the inner wall of the separating post 20 directly contacts the pad 50. Typically, the separating posts 20 are in the form of cylindrical collars. The solder balls 30 are accommodated in the separating posts 20, to avoid a short connection between any two adjacent solder balls 30.

Thus in the package assembly 100, the solder balls 30 are separated from each other by the separating posts 20. This avoids tin bridging during an encapsulation process when manufacturing the package assembly 100. In addition, it means that the package assembly 100 can have a reduced size.

In the embodiment, the material of the separating posts 20 is copper. Due to the high electrical conductivity and high thermal conductivity of copper, setting the separating posts 20 on the substrate 10 can increase the heat radiation (i.e. dissipation) capability of the package assembly 100. Alternatively, the separating posts 20 can be made of another suitable metallic material, for example aluminum.

In the embodiment, each two adjacent separating posts 20 are separated a distance. For example, the distance separating each two adjacent separating posts 20 is about 40 μm. As a result, compared with conventional technology, the distance between each two adjacent pads 50 is greatly reduced. Therefore the size of the package assembly 100 is reduced, allowing miniaturization of the package assembly 100.

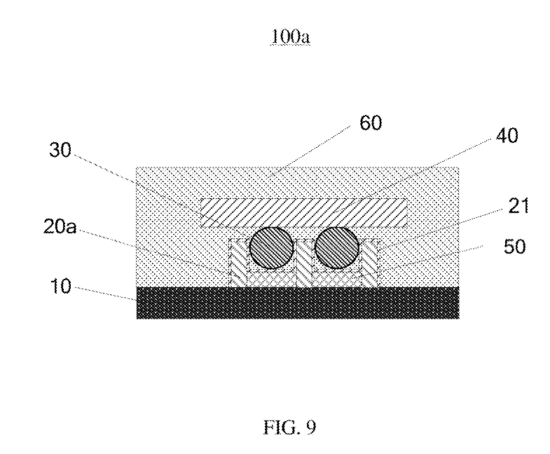

FIG. 9 shows a package assembly 100a for a chip, according to a second exemplary embodiment of the disclosure. The package assembly 100a is similar to the package assembly 100. However, in the package assembly 100a, every two adjacent separating posts 20a share a common wall portion where the adjacent separating posts 20a meet. The common wall portion is located between two corresponding pads 50. A thickness of the common wall portion is least at a middle of the common wall portion. For example, this minimum thickness is about 40 μm. As a result, compared with conventional technology, the distance between each two adjacent pads 50 is greatly reduced. Therefore the size of the package assembly 100a is reduced, allowing miniaturization of the package assembly 100a.

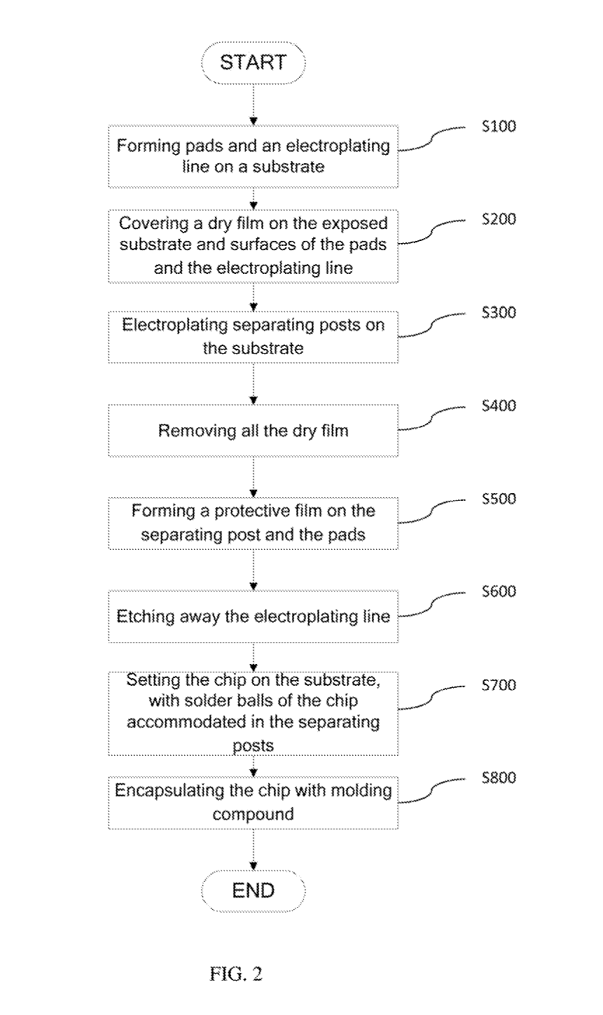

In each of the package assemblies 100, 100a, the chip 40 is encapsulated over the substrate 10 by the encapsulation 60. Referring to FIG. 2, an exemplary method of manufacturing the package assembly 100 comprises the following steps.

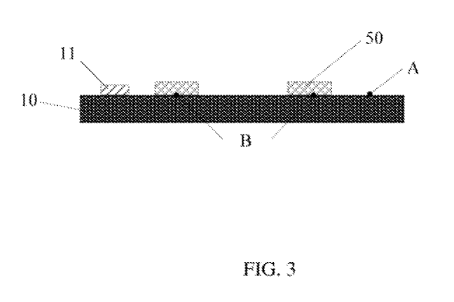

FIG. 3 shows that in step S100, the substrate 10 is divided into a first area A and a number of second areas B. The second areas B are discrete, and are located among corresponding gaps in the first area A. That is, the first area A is patterned insofar as it defines the gaps. Each second area B corresponds to one pad 50 to be formed. The second areas B underlie and surround the corresponding pads 50 once the pads 50 are formed. The pads 50 are duly formed on the second areas B of the substrate 10, and simultaneously an electroplating line 11 is formed on a portion of the first area A near one side edge of the substrate 10.

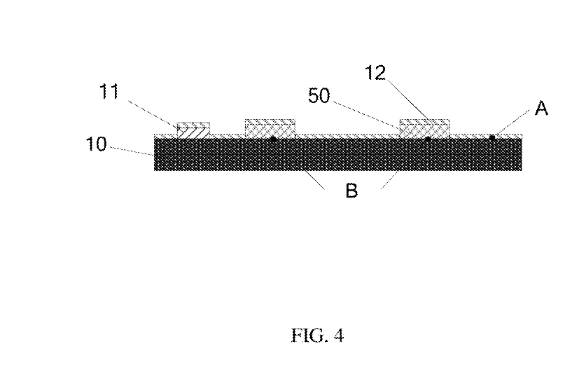

FIG. 4 shows that in step S200, a dry film 12 is covered on the exposed substrate 10 and on surfaces of the pads 50 and the electroplating line 11 to avoid oxidation.

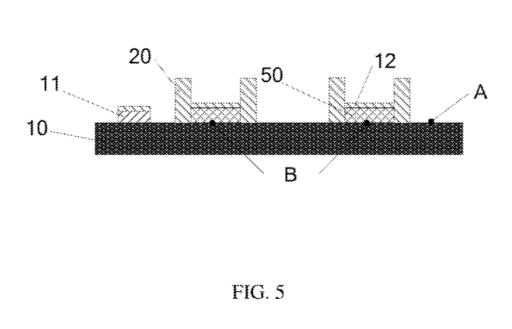

FIG. 5 shows that in step S300, portions of the dry film 12 on the substrate 10 are removed. In the embodiment, the dry film 12 is removed by liquid chemical etching. Then the separating posts 20 are electroplated on the second areas B. The separating posts 20 extend from the substrate 10 at edges of the corresponding pads 50 in a direction away from the substrate 10. In the embodiment, the overall width of each separating post 20 is 40 μm, and the material of the separating post 20 is copper. Alternatively, the separating posts 20 can be made of another suitable metallic material, for example aluminum.

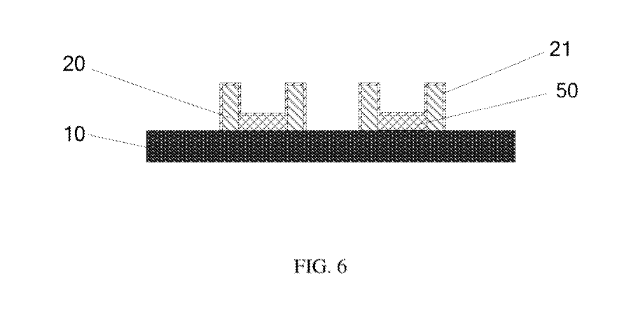

FIG. 6 shows that in step S400, all the remaining portions of the dry film 12 are removed. In the embodiment, the dry film 12 is removed by liquid chemical etching.

FIG. 6 also shows that in step S500, a protective film 21 is formed on the separating posts 30 and the pads 50. The protective film 21 is formed by electroplating nickel-gold alloy or by melting organic protective film at high temperature. The protective film 21 ensures the electrical conductivity of the pads 50.

FIG. 6 further shows that in step S600, the electroplating line 11 is etched away, because it is superfluous.

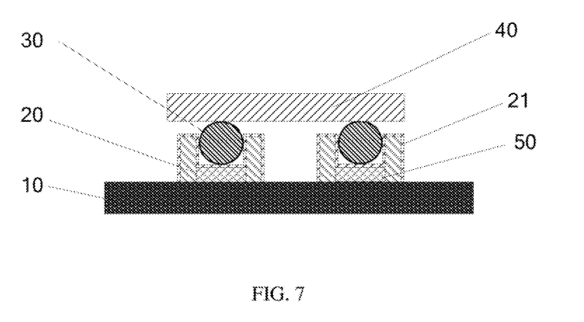

FIG. 7 shows that in step S700, the chip 40 is soldered on the solder balls 30. Then the solder balls 30 are accommodated in the separating posts 20 and are electrically connected to the pads 50. Thus, the chip 40 is set on the substrate 10.

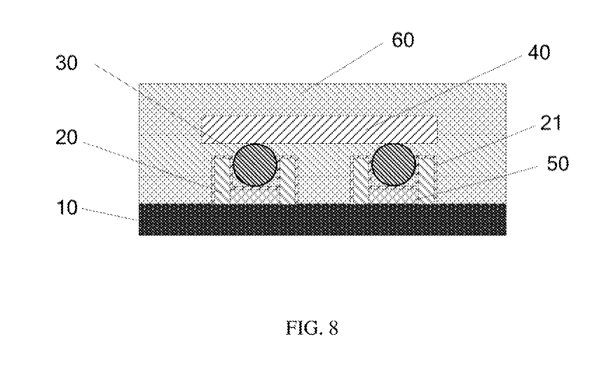

FIG. 8 shows that in step S800, the chip 40 is encapsulated by the encapsulation 60, which fastens the chip 40 on the substrate 10. In the embodiment, molding compound is used as the encapsulation 60, which encapsulates the chip 40.

In summary, taking the package assembly 100 and the above-described manufacturing method as examples, the separating posts 20 are electroplated on the substrate 10, the solder balls 30 are set in the separating posts 20, and the chip 40 is encapsulated in the encapsulation 60. These configurations avoid tin bridging. The distance separating each two adjacent solder balls 30 can be adjusted as needed. Furthermore, in the case of the package assembly 100a, the effective superposition of the two adjacent separating posts 20a to form a common wall portion reduces the distance separating the two corresponding adjacent pads 50. For each of the package assemblies 100, 100a, the overall size of the package assembly 100, 100a can be reduced. Thus the package assembly 100, 100a is suitable for high density package applications such as packaging of a flip chip.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A package assembly for a chip, the package assembly comprising:
a substrate;
a pad located on the substrate, a hollow post extending from the substrate at an edge of the pad in a direction away from the substrate, the post surrounding the pad;
a solder ball located on the pad in the hollow post, the solder ball electrically connected to the pad;
a chip electrically connected to the pad via the solder ball; and
an encapsulation encapsulating all of the pad, the solder ball and the chip on the substrate therein.

2. The package assembly of claim 1, wherein the material of the post is copper.

3. The package assembly of claim 1, further comprising at least one other hollow post, wherein every two adjacent posts meet and share a common wall portion.

4. The package assembly of claim 3, wherein a minimum thickness of the common wall portion is 40 micrometers (μm).

5. The package assembly of claim 1, wherein an overall width of each post is 40 μm.

6. The package assembly of claim 1, wherein a distance separating every two adjacent posts is 40 micrometers (μm).

7. A package assembly manufacturing method, comprising:
forming a pad on a substrate;
forming a hollow post on the substrate, the post extending from the substrate at an edge of the pad in a direction away from the substrate, and the post surrounding the pad;
providing a chip with a solder ball;
positioning the solder ball on the pad in the post, and electrically connecting the solder ball to the pad such that the chip is electrically connected to the pad via the solder ball; and
encapsulating all of the pad, the solder ball and the chip on the substrate in an encapsulation.

8. The method of claim 7, wherein the post is formed on the substrate by electroplating.

9. The method of claim 7, further comprising, after positioning the solder ball on the pad in the post and before electrically connecting the solder ball to the pad, forming a protective film on the post and the pad.

10. The method of claim 9, wherein the protective film is formed by electroplating nickel-gold alloy or by melting organic protective film.

11. The method of claim 7, wherein a plurality of the pads are formed on the substrate, the chip has a plurality of the solder balls, each solder ball is located on a corresponding one of the pads, and each two adjacent posts separate the corresponding two solder balls.
